(19) United States
(12) Patent Application Publication
(10) Pub. No.: US 2011/0049622 A1
(43) Pub. Date: Mar. 3, 2011

(54) SEMICONDUCTOR DEVICE AND METHOD OF MANUFACTURING THE SAME

(75) Inventor: Hiroyoshi Kitahara, Oita-ken (JP)

(73) Assignee: KABUSHIKI KAISHA TOSHIBA, Tokyo (JP)

(21) Appl. No.: 12/719,271

(22) Filed: Mar. 8, 2010

(30) Foreign Application Priority Data
Aug. 27, 2009 (JP) 2009-197129

(51) Int. Cl. H01L 29/78; H01L 21/22

(52) U.S. Cl. 257/337; 438/561; 257/347; 257/E29.256; 257/E21.135

(57) ABSTRACT

A semiconductor device has an insulating film and an n-type buried layer. The insulating film is formed in a flat-shaped cavity formed inside a p-type semiconductor substrate and in a trench extending from a surface of the semiconductor substrate to the cavity. The buried layer is formed in surrounding regions of the cavity and the trench in the semiconductor substrate.

### CROSS-REFERENCE TO RELATED APPLICATION

This application is based upon and claims the benefit of priority from the prior Japanese Patent Application No. 2009-197129, filed on Aug. 27, 2009; the entire contents of which are incorporated herein by reference.

### FIELD OF THE INVENTION

The invention relates to a semiconductor device and a method of manufacturing the semiconductor device.

### DESCRIPTION OF THE BACKGROUND

An SOI (Silicon-On-Insulator) substrate is known as a semiconductor substrate in which an insulating layer is formed. The use of the SOI substrate facilitates formation of a semiconductor device which has high withstanding voltage characteristics, and high-temperature performance. In addition, by forming an n-type buried layer in the semiconductor substrate, an npn-type bipolar transistor and a DMOS (Double-diffused Metal-Oxide-Semiconductor) which have high withstanding voltage characteristics and high surge breakdown voltage characteristics can be formed.

Conventional methods of manufacturing the SOI substrate, as disclosed in Japanese Patent Application Publication No. 9-64319, are mainly classified into the following two methods. One is a SIMOX (Separation by Implanted Oxygen) method in which oxygen ions are implanted into a single crystal semiconductor substrate to a predetermined depth from the surface of the substrate by means of an ion implantation method, and then, a buried oxide film is formed by annealing around an area where the oxygen ions are implanted. The other is a bonding method in which two single crystal semiconductor substrates are bonded to each other with an oxide film interposed in between first, and then, the surface of one of the semiconductor substrates is polished or etched so as to be a semiconductor film.

As disclosed in Japanese Patent Application Publication No. 2008-172112, the semiconductor substrate having a buried layer is formed by depositing an n-type buried layer and a p-type epitaxial layer in this order on a p-type single crystal semiconductor substrate, for example.

In addition, an SOI substrate having an n-type buried layer with a structure in which the SOI substrate and a substrate having the n-type buried layer are combined is conventionally known. Methods of manufacturing an SOI substrate having a buried layer include, as disclosed in Japanese Patent Application Publication No. 2008-10668, a method in which an n-type impurity is implanted into the surface of the SOI substrate and then the buried layer is epitaxially grown when the SOI substrate is manufactured by the SIMOX method or the bonding method, and a method in which an n-type impurity is previously implanted into a semiconductor substrate to be processed into semiconductor devices, when the SOI substrate is manufactured by the bonding method.

However, both the methods of manufacturing an SOI substrate having a buried layer are disadvantageously high in cost. In addition, in manufacturing the substrate by the latter bonding method, the semiconductor substrates are bonded to each other after the n-type impurity layer is formed. For this reason, an area where the n-type impurity layer is formed has to have a margin large enough to allow a position error of a semiconductor element formed on the surface of the semiconductor substrate, with respect to the formation position of the n-type impurity layer in an in-plane direction. As a result, the semiconductor substrate and the semiconductor device manufactured using the semiconductor substrate become large in size, leading to an increase in cost.

### SUMMARY OF THE INVENTION

One aspect of the invention is to provide a semiconductor device that may comprise an insulating film formed in a flat-shaped cavity formed inside a semiconductor substrate of a first conductivity type and in a trench extending from a surface of the semiconductor substrate to the cavity, and a buried layer of a second conductivity type formed in surrounding regions of the cavity and the trench in the semiconductor substrate.

Another aspect of the invention is to provide a method of manufacturing a semiconductor device that may comprise forming a flat-shaped cavity in a predetermined depth inside a semiconductor substrate of a first conductivity type, forming a trench extending from a surface of the semiconductor substrate to the cavity, forming an impurity diffusion source layer including an impurity of a second conductivity type on inner walls of the cavity and the trench through the trench, forming an insulating film on the impurity diffusion source layer formed inside the cavity and the trench through the trench, and forming a buried layer by diffusing the impurity of the second conductivity type included in the impurity diffusion source layer into the semiconductor substrate around the cavity through heat treatment.

### BRIEF DESCRIPTION OF THE DRAWINGS

FIGS. 1A and 1B are views schematically showing a part of a configuration of a semiconductor device according to a first embodiment.

FIGS. 2-1A, 2-1B and 2-1C are sectional views (1) showing an example of a method of manufacturing a semiconductor substrate according to the first embodiment. FIGS. 2-2A, 2-2B and 2-2C are sectional views (2) showing an example of the method of manufacturing the semiconductor substrate according to the first embodiment. FIG. 2-3 is a sectional view (3) showing an example of the method of manufacturing the semiconductor substrate in the first embodiment.

FIG. 3 is a view schematically showing an example of a state in which an insulating film is formed in a cavity.

FIGS. 4A, 4B and 4C are sectional views schematically showing an example of a semiconductor device manufactured using the semiconductor substrate according to the first embodiment.

FIGS. 5A and 5B are views schematically showing another configuration example of the semiconductor device in according to the first embodiment.

FIGS. 6A and 6B are views schematically showing a configuration of a semiconductor device according to a second embodiment.

FIGS. 7-1A, 7-1B and 7-1C are sectional views (1) schematically showing an example of a method of manufacturing a semiconductor substrate according to the second embodiment. FIG. 7-2 is a sectional view (2) schematically showing an example of the method of manufacturing the semiconductor substrate according to the second embodiment.

FIG. 8 is a sectional view schematically showing a part of a configuration of a semiconductor device according to a third embodiment.

FIGS. 9-1A, 9-1B and 9-1C are sectional views (1) showing an example of a method of manufacturing the semiconductor device according to a third embodiment. FIGS. 9-2A, 9-2B and 9-2C are sectional views (2) showing an example of the method of manufacturing the semiconductor device according to the third embodiment.

FIG. 10 is a sectional view schematically showing an example of a semiconductor device manufactured using the semiconductor substrate according to the third embodiment.

### DETAILED DESCRIPTION OF THE INVENTION

Semiconductor devices in embodiments of the invention and methods of manufacturing the semiconductor devices will be described below in details with reference to the appended drawings. Note that, these embodiments do not limit the invention. In addition, the sectional views of the semiconductor substrates and the semiconductor devices, which are used in the following embodiments, are schematic and therefore, relationship between thickness and width of layers and ratio of each layer in thickness are different from those in actual cases. Further, the below-mentioned film thickness is merely an example and the invention is not limited to this.

### First Embodiment

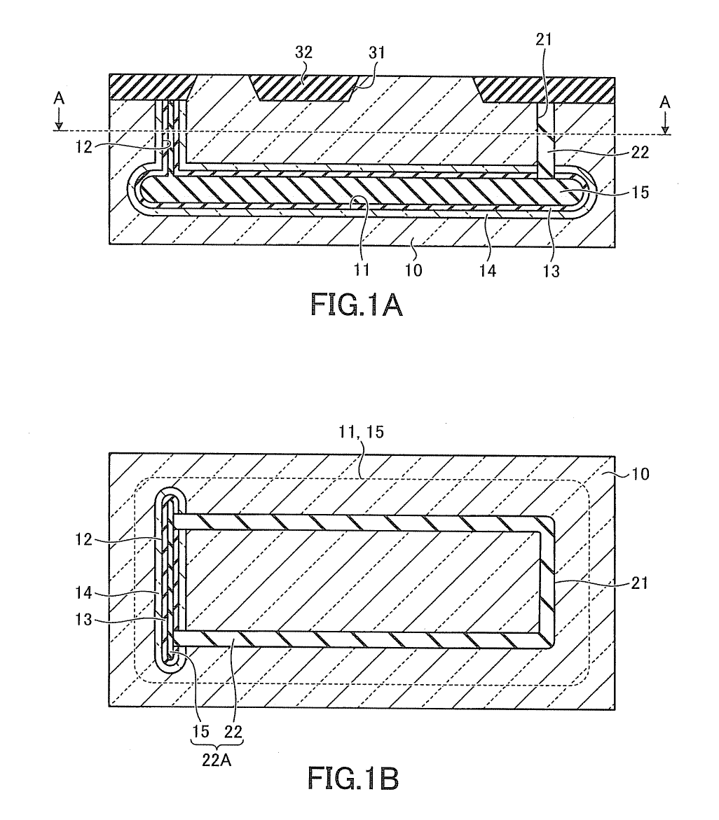

FIGS. 1A and 1B are views schematically showing a part of the configuration of the semiconductor device according to a first embodiment. FIG. 1A is a sectional view, and FIG. 1B is a top view showing a state in which the semiconductor device is cut along a position corresponding to an A-A plane in FIG. 1A. The semiconductor substrate is constituted of a p-type single crystal silicon substrate 10 in which SON (Silicon On Nothing) is formed in a predetermined region (for example, in the silicon substrate corresponding to an element forming region). In other words, a flat-shaped cavity 11 is formed in a predetermined depth inside the silicon substrate 10 at a certain timing during a manufacturing process. The cavity 11 is rectangular in a plan view. Moreover, a film forming trench 12 which extends from the surface of the silicon substrate 10 to the cavity 11, and which is provided to form a film in the cavity 11 is formed in a part of a forming region of the cavity 11. The film forming trench 12 is formed along a left side of the cavity 11 in FIG. 1A.

An n-type impurity diffusion source layer 13 as a diffusion source for n-type impurity such as AsSG (Arsenic Silicate Glass) is formed on inner walls of the cavity 11 and the film forming trench 12. An n-type buried layer 14 in which the n-type impurity is diffused is formed in surrounding regions of the n-type impurity diffusion source layer 13 in the silicon substrate 10.

An insulating film 15 such as a TEOS (Tetraethyl Orthosilicate) film is formed so as to fill in the cavity 11 and the film forming trench 12 on which the n-type impurity diffusion source layer 13 is formed. Here, the cavity 11 may be completely filled with the insulating film 15 without any gap or have a gap remaining at the center of the cavity 11.

A deep trench isolation (DTI) film (hereinafter, referred to as a DTI film) 22 as a first isolation film which extends from the surface of the silicon substrate 10 to the insulating film 15 in the cavity 11 to isolate elements from each other and defines an element forming region is formed. The DTI film 22 is formed at an inner side of the forming region of the cavity 11 in the shape of an inverted C in a plan view. Two open ends of the DTI film 22 in the shape of an inverted C are connected to the film forming trench 12. As a result, in a plan view, the cavity 11 in the shape of an inverted C is combined with the insulating film 15 in the film forming trench 12 to constitute a frame-like DTI film 22A as a whole.

A shallow trench isolation film (hereinafter, referred to as an STI film) 32 as a second isolation film to isolate diffusion layers (regions) adjacent to each other at a shallow position from the surface of the silicon substrate 10 is formed at a position in a determined region, which is shallower than that of the DTI film 22 in the forming region of the cavity 11. The STI film 32 is formed at the position on the DTI film 22 and the position above the cavity 11 other than the DTI film 22 forming position.

Although not shown, an npn-type bipolar transistor, a field-effect transistor (hereinafter, referred to as a MOS transistor), a DMOS transistor or the like is formed in a region surrounded by the DTI film 22.

The semiconductor substrate according to the first embodiment has the SOI structure in which the insulating film 15 is filled in the cavity 11 of the p-type silicon substrate 10, and the insulating film 15 is surrounded by the n-type buried layer 14.

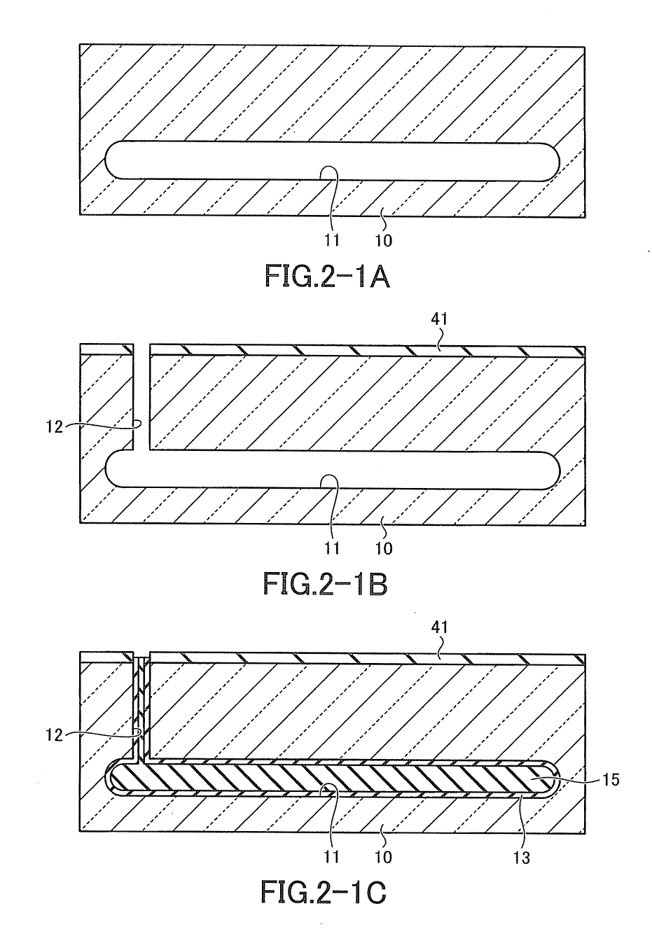

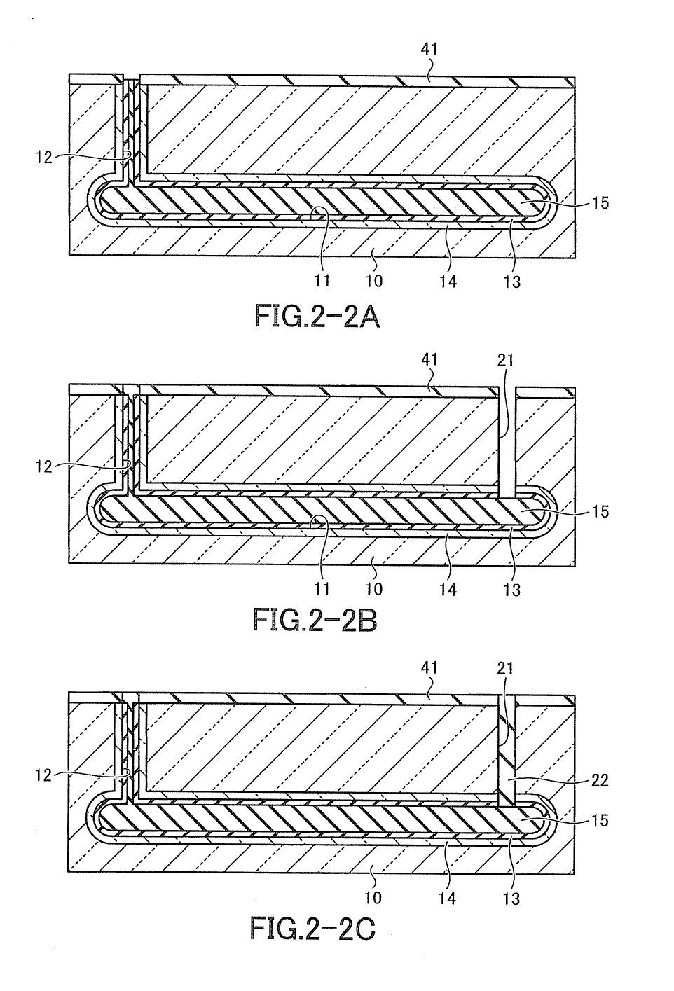

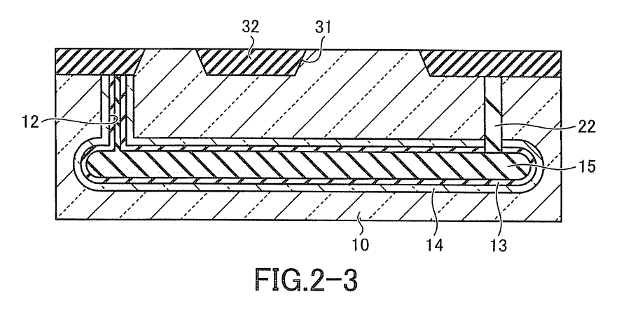

Next, a method of manufacturing the semiconductor substrate will be described. FIGS. 2-1A through 2-3 are sectional views showing an example of the method of manufacturing the semiconductor substrate according to the first embodiment. As shown in FIG. 2-1A, an SON is formed in the p-type single crystal silicon substrate 10 as the semiconductor substrate. A method of forming the SON is described in T. Sato et al., “SON (Silicon on Nothing) MOSFET using ESS (Empty Space in Silicon) technique for SoC applications,” IEDM Tech Digest, USA, IEEE, 1999, pp. 510-517, and an example of the method will be briefly described below. First, a mask layer is formed on the surface of the silicon substrate 10, and a stripe pattern is formed by a photolithography technique in a region where the cavity 11 is to be formed. Next, the silicon substrate 10 is etched using the stripe pattern as a mask by using a RIE (Reactive Ion Etching) method to form trenches. After removal of the mask material, the substrate is subjected to annealing at high temperature of 1100° C. in a nonoxidizing atmosphere under a reduced pressure. High-temperature annealing causes a migration phenomenon of silicon atoms, resulting in that each opened surface of the trenches is closed, and cavities formed at bottoms of the trenches are united into the flat-shaped cavity 11. Here, since the above-mentioned document describes that the shape of the cavity 11 formed in the silicon substrate 10 can be changed by changing a configuration of the trenches formed on the silicon substrate 10, the cavity 11 corresponding to a desired element forming region can be formed.

As shown in FIG. 2-1B, a silicon nitride film 41 functioning as an etching stopper film in a CMP (Chemical Mechanical Polishing) method to be performed later is formed on one of main surfaces of the silicon substrate 10 (hereinafter, referred to as an upper surface). Furthermore, a resist (not shown) is applied onto the silicon nitride film 41, and a pattern to form the film forming trench 12 connected to the cavity 11 is formed by a photolithography technique. The film forming trench 12 is formed in the vicinity of a left end of the cavity 11. The silicon nitride film 41 and the silicon substrate 10 are etched using the resist pattern as a mask by the RIE method to form the film forming trench 12 extending to the cavity 11.

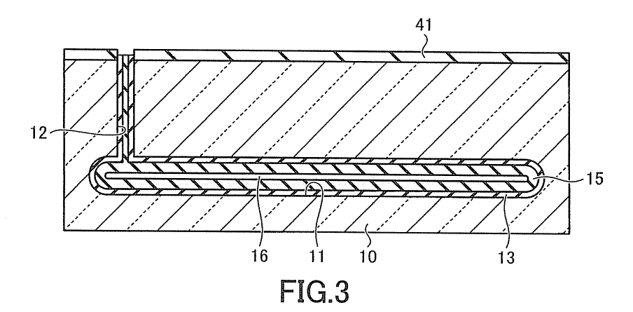

As shown in FIG. 2-1C, the n-type impurity diffusion source layer 13 such as an AsSG film or a PSG (Phospho-Silicate Glass) film as a diffusion source into the n-type buried layer 14 is deposited by a CVD (Chemical Vapor Deposition) method along inner walls as interfaces defining the film forming trench 12 and the cavity 11. Subsequently, the insulating film 15 formed of a TEOS film is deposited in the cavity 11 and the film forming trench 12. FIG. 3 is a view schematically showing an example of a state where the insulating film 15 is formed in the cavity 11. Although the cavity 11 is completely filled with the insulating film 15 without any gap in FIG. 2-1C, a gap 16 may be left in the center portion of the flat-shaped cavity 11 as shown in FIG. 3. After the insulating film 15 is formed in the cavity 11 and the film forming trench 12, the insulating film 15 formed on the upper surface of the silicon nitride film 41 is removed by the CMP method or the RIE method. The silicon nitride film 41 functions as the stopper film.

As shown in FIG. 2-2A, the n-type impurity is diffused from the n-type impurity diffusion source layer 13 into the silicon substrate 10 by annealing. As a result, the n-type buried layer 14 is formed on the silicon substrate 10 in the surrounding regions of the cavity 11 and the film forming trench 12. Note that, since the n-type buried layer 14 is formed around the cavity 11, the forming position of the n-type buried layer 14 is substantially the same as that of the cavity 11. A position error of a semiconductor element such as an npn-type bipolar transistor, a field-effect transistor or a DMOS transistor, which is formed in the subsequent manufacturing process, from the n-type buried layer 14 in an in-plane direction of the silicon substrate 10 is the same as that of the semiconductor element from the cavity 11. In addition, since the semiconductor element is formed following the formation of the cavity 11 and the n-type buried layer 14, it is relatively easy to form the semiconductor element while adjusting the semiconductor element to the forming position of the cavity 11 (the n-type buried layer 14).

On the contrary, according to a conventional method, for example, in the case where an SOI substrate is bonded to a bonding substrate on which an n-type impurity layer is formed, there is a possibility that a position of the n-type impurity layer at bonding deviates from a target position in the in-plane direction of the substrate. Further, in order for a semiconductor element to be formed in a forming region of the n-type impurity layer, a large margin needs to be secured so as to allow a transverse position error between the n-type impurity layer and the semiconductor element. Thus, according to the conventional method, the semiconductor substrate may be large, hence leading to an increase in cost. According to the first embodiment, the position error between the n-type buried layer 14 and the semiconductor element in the in-plane direction of the substrate may be reduced as compared to the conventional method.

As shown in FIG. 2-2B, after a mask layer formed of a silicon oxide film (not shown), for example, is formed on the silicon nitride film 41, a resist is applied onto the mask layer, and the resist is patterned so that the forming position of the DTI film 22 can be opened. Then, the mask layer is etched using the resist pattern as a mask by the RIE method. The mask layer having an opened region where the DTI film 22 is made is formed through etching. The silicon substrate 10 is etched using the mask layer as a mask by the RIE method. The silicon substrate 10, the n-type buried layer 14, the n-type impurity diffusion source layer 13 and the insulating film 15 are etched down to the insulating film 15 in the cavity 11. As a result, a deep trench 21 is formed.

An insulating film having flowability at the time of film-formation, that is, initial flowability such as a TEOS film is buried in the deep trench 21 by a film-forming method such as the CVD method. The insulating film is formed so that the upper surface of the insulating film can be higher than that of the silicon nitride film 41. As shown in FIG. 2-2C, the insulating film formed higher than the silicon nitride film 41 is removed using the silicon nitride film 41 as a stopper film. The DTI film 22 to electrically isolate the element forming region from the other region is formed in the silicon substrate 10.

As shown in FIG. 2-3, the STI film 32 is formed on the upper surface of the silicon substrate 10 according to a well-known method. A resist (not shown) is applied onto the silicon nitride film 41, for example, and a resist pattern having an opened region where the STI film 32 is formed is formed by the photolithography technique. The silicon nitride film 41 is etched using the resist pattern as a mask by the RIE method or the like to transfer the resist pattern. The silicon substrate 10 is etched using, as a mask, the silicon nitride film 41 on which the pattern is formed. A shallow trench 31 is formed by the etching. An insulating film having initial flowability such as the TEOS film is formed on the upper surface of the silicon substrate 10 on which the shallow trench 31 is formed by the film forming method such as the CVD method, and the insulating film on the silicon nitride film 41 is removed by using the silicon nitride film 41 as a stopper film by the CMP method. The STI film 32 can be formed in the shallow trench 31 by selectively removing the silicon nitride film 41. In this manner, the semiconductor substrate according to the first embodiment is obtained. After that, semiconductor elements are formed by a well-known method in the element forming region surrounded by the DTI film 22.

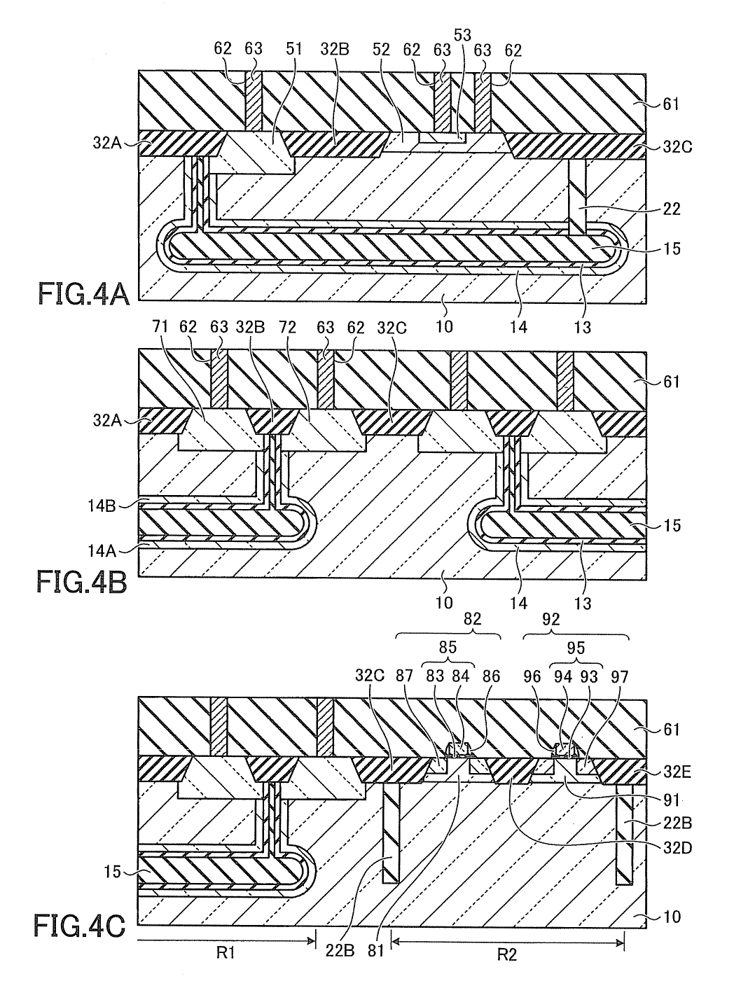

FIGS. 4A through 4C are sectional views schematically showing an example of the semiconductor device manufactured using the semiconductor substrate according to the first embodiment. FIG. 4A shows an example of the semiconductor device in which npn-type bipolar transistors are formed in the element forming region defined by the DTI film 22 and the insulating film 15 in the film forming trench 12 of the semiconductor substrate obtained through the steps shown in FIGS. 2-1A through 2-3. In other words, in a region surrounded by STI films 32A, 32B in the element forming region, a collector lead layer 51 formed of an n-type diffusion layer is formed so as to be deeper than the STI film 32. In a region surrounded by STI films 32B, 32C, a base layer 52 formed of a p-type diffusion layer is formed so as to have the substantially same depth as the STI film 32. An emitter layer 53 formed of an n-type diffusion layer is formed in a shallow region in the base layer 52. An interlayer insulating film 61 formed of an insulating film such as a silicon oxide film is formed on the semiconductor substrate on which the npn-type bipolar transistor is formed. Contact holes 62 penetrating the interlayer insulating film 61 in the thickness direction are provided at each forming position of the collector lead layer 51, the base layer 52 and the emitter layer 53. Lead electrodes 63 are formed in each of the contact holes 62 by burying a conductive material.

A method of manufacturing the semiconductor device will be briefly described without reference to figures. First, a resist is applied onto the semiconductor substrate in FIG. 2-3 and patterned by the photolithography technique so as to open a region to which ions are implanted, and then, impurity ions of each conductive type are implanted in accordance with each opening by the ion implantation method for activation. For example, in the case where a resist pattern having the opened region surrounded by the STI films 32A, 32B is formed, n-type impurity ions are implanted to form the collector lead layer 51 so that the collector lead layer 51 can be deeper than bottom surfaces of the STI films 32A, 32B. In the case where a resist pattern having the opened region surrounded by the STI films 32B, 32C is formed, p-type impurity ions are implanted to form the base layer 52 so that the base layer 52 can be substantially the same as or slightly shallower than bottom surfaces of the STI films 32B, 32C. In the case where a resist pattern having the opened region around the center portion of the base layer 52 is formed, n-type impurity ions are implanted to form the emitter layer 53 so that the emitter layer 53 can be shallower than the base layer 52.

Then, according to a well-known method, the interlayer insulating film 61 is formed on the upper surface of the silicon substrate 10, the contact holes 62 are formed in the interlayer insulating film 61 and the lead electrodes 63 are formed in the contact holes 62, respectively, by burying the conductive material.

Note that, although the case where the npn-type bipolar transistor is formed has been described, the field-effect transistor, the DMOS transistor or the like may be formed in the element forming region.

FIG. 4B shows an example of the semiconductor device in which electrodes are formed inside and outside the element forming region of the semiconductor substrate obtained through the steps shown in FIGS. 2-1A through 2-3, the element forming region defined by the DTI film 22 and the insulating film 15 in the film forming trench 12. In the region surrounded by the STI films 32A, 32B formed in the element forming region, an upper lead n-type diffusion layer 71 is formed so as to be deeper than the STI films 32A, 32B. In the region surrounded by the STI films 32B, 32C formed outside of the element forming region, a lower lead n-type diffusion layer 72 is formed so as to be deeper than the STI films 32B, 32C. The upper lead n-type diffusion layer 71 is connected to the n-type buried layer 14B formed along surrounding regions of the cavity 11 and the film forming trench 12 in the element forming region. The lower lead n-type diffusion layer 72 is connected to the n-type buried layer 14A formed along the surrounding regions of the cavity 11 and the film forming trench 12 outside of the element forming region. The interlayer insulating film 61 formed of a silicon oxide film is formed on the semiconductor substrate on which the n-type diffusion layers 71, 72 are formed. The contact holes 62 penetrating the interlayer insulating film 61 in the thickness direction are formed at the forming positions of the upper lead n-type diffusion layer 71 and the lower lead n-type diffusion layer 72, respectively. The lead electrode 63 is formed in each of the contact holes 62 by burying a conductive material. The semiconductor device is formed in the similar manner to the method described with reference to FIG. 4A.

FIG. 4C shows an example of the semiconductor device in which only the DTI film 22B without the flat-shaped insulating film 15 and the surrounding n-type buried layer 14 is formed outside of a first element forming region R1 corresponding to the forming region of the cavity 11 on the semiconductor substrate obtained through the steps shown in FIGS. 2-1A through 2-3, and the semiconductor elements are formed in a second element forming region R2 defined by the DTI film 22B.

The second element forming region R2 defined by the DTI film 22B is formed on the outside of the first element forming region R1 of the semiconductor substrate obtained through the steps shown in FIGS. 2-1A through 2-3, in which the flat-shaped insulating film 15 is formed. A p-type well 81 is formed in a region defined by STI films 32C, 32D in the second element forming region R2, and an n-type MOS transistor 82 is formed on the p-type well 81. An n-type well 91 is formed in a region defined by the STI films 32D, 32E, and a p-type MOS transistor 92 is formed on the n-type well 91. Both of the p-type well 81 and the n-type well 91 are formed so as to have the substantially same depth as the STI films 32C to 32E. Note that, the first element forming region R1 has the configuration shown in FIG. 4B.

A method of manufacturing the semiconductor device will be briefly described. Here, it is assumed that the element forming region in which the flat-shaped insulating film 15 formed through the steps shown in FIGS. 2-1A through 2-3 is the first element forming region R1. In the process described with reference to FIGS. 2-1A through 2-3, the DTI film 22B and the STI films 32C to 32E are formed in a region other than the first element forming region R1, on which the flat-shaped cavity 11 is not formed, and the second element forming region R2 having no flat-shaped insulating film 15 and n-type buried layer 14 is formed. The p-type well 81 and the n-type well 91 are formed in the region defined by the STI films 32C, 32D and the region defined by the STI films 32D, 32E in the second element forming region R2, respectively.

The n-type MOS transistor 82 and the p-type MOS transistor 92 are formed on the p-type well 81 and the n-type well 91, respectively, by a well-known method. In other words, a laminated body 85 formed of a gate insulating film 83 and a gate electrode 84 is formed on the p-type well 81, and side wall spacers 86 are formed on side surfaces of the laminated body 85 in a line width direction. After that, n-type impurity ions are implanted to the laminated body 85 and the surface of the silicon substrate 10 surrounded by the STI films 32C, 32D and activated to form source/drain regions 87, and the n-type MOS transistor 82 is formed. A laminated body 95 formed of a gate insulating film 93 and a gate electrode 94 is formed on the n-type well 91, and side wall spacers 96 are formed on side surfaces of the laminated body 95 in the line width direction. After that, p-type impurity ions are implanted to the laminated body 95 and the surface of the silicon substrate 10 surrounded by the STI films 32D, 32E and activated to form source/drain regions 97, and the p-type MOS transistor 92 is formed. Then, as described above, the interlayer insulating film 61 is formed, the contact holes are made at necessary positions, and lead electrodes are formed by burying the conductive material into the contact holes.

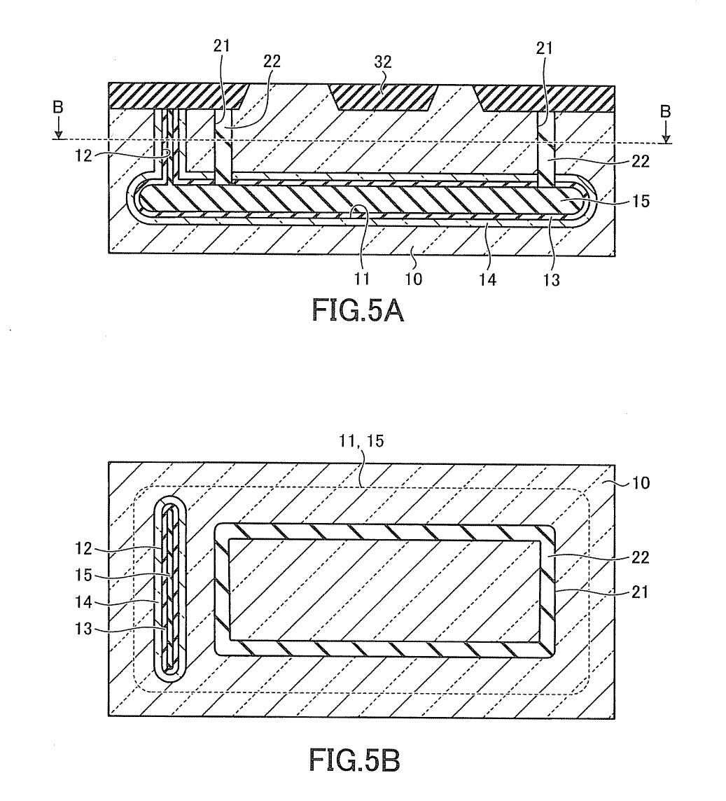

FIGS. 5A and 5B are views schematically showing another configuration example of the semiconductor device according to the first embodiment. FIG. 5A is a sectional view, and FIG. 5B is a top view showing the semiconductor device cut along a B-B plane in FIG. 5A. In the example shown in FIGS. 1A and 1B, the insulating film 15 in the film forming trench 12 is used as a part of the DTI film 22A. On the other hand, in the example shown in FIGS. 5A and 5B, the insulating film 15 in the film forming trench 12 is not used as a part of the DTI film 22, and the frame-like DTI film 22 is formed in the region where the flat-shaped insulating film 15 is formed. The same reference numerals are given to the same components as those in FIGS. 1A and 1B. A method of manufacturing the semiconductor substrate is similar to the manufacturing method shown in FIGS. 2-A through 2-3.

As described above, according to the first embodiment, the flat-shaped cavity 11 (SON) is formed in the necessary region in the semiconductor substrate, and the impurity diffusion source layer 13 to form the n-type buried layer 14 is formed in the surrounding region of the cavity 11. Moreover, after the insulating film 15 such as the TEOS film is filled in the impurity diffusion source layer 13, the n-type buried layer 14 is formed in the surrounding region of the cavity 11 by annealing. The same configuration as a buried SiO₂ layer of an SOI substrate may be formed within the semiconductor substrate, that is, locally formed. The SOI substrate having the n-type buried layer 14 can be manufactured at a low cost as compared to the conventional method. Since the semiconductor substrate and the semiconductor device are continuously manufactured, the position error of the forming position of the semiconductor element from the forming position of the cavity 11 (n-type buried layer 14) in the in-plane direction can be reduced as compared to the conventional method. As a result, a margin set to the cavity 11 may be reduced, resulting in that the semiconductor substrate can be advantageously made smaller than the conventional semiconductor substrate.

In addition, since the impurity diffusion source layer 13 is formed from the cavity 11 to the surface of the semiconductor substrate along the film forming trench 12 used to form the impurity diffusion source layer 13 and the insulating film 15 in the cavity 11, the lead electrode can be easily formed by using the n-type buried layer 14. In the conventional method, in order to form the lead electrode of the n-type buried layer, a high-acceleration ion implantation technique and high temperature heat treatment for a long time to diffuse the impurity implanted from the surface down to the n-type buried layer have been needed. However, according to the first embodiment, the lead electrode of the n-type buried layer can be formed without using these conventional techniques. Similarly, lead of an electrode around each flat-shaped insulating film 15 can be easily achieved.

### Second Embodiment

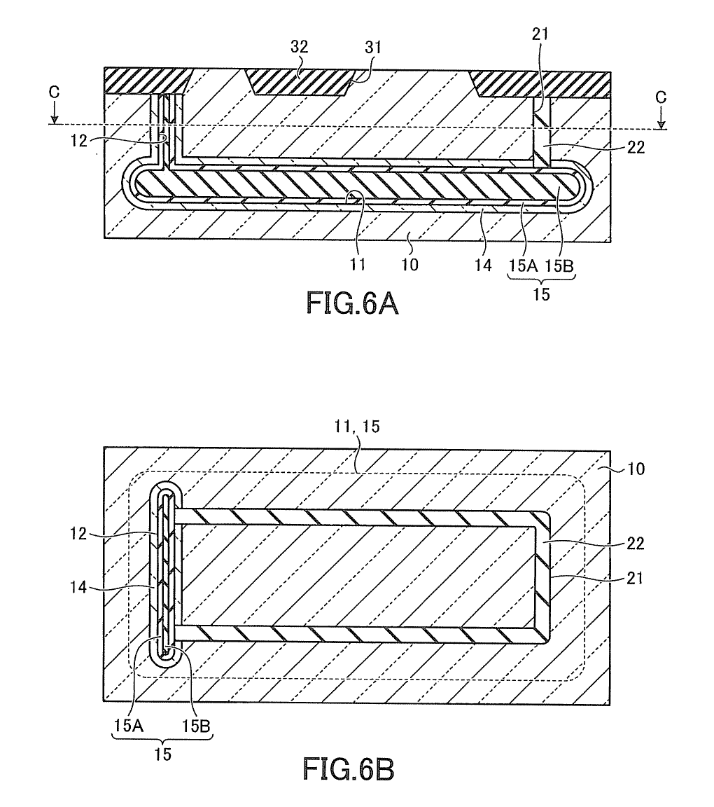

FIGS. 6A and 6B are views schematically showing a configuration of a semiconductor device according to a second embodiment. FIG. 6A is a sectional view, and FIG. 6B is a top view showing a state in which the semiconductor device is cut along a position corresponding to a C-C plane in FIG. 6A. The semiconductor substrate in this embodiment is different from the semiconductor substrate in the first embodiment in that the n-type impurity diffusion source layer 13 in the cavity 11 is removed, and that the insulating film 15 has a two-layered configuration constituted of a silicon oxide film 15A formed along an inner wall of the cavity 11 and a TEOS film 15B formed in the cavity 11 covered with the silicon oxide film 15A. The same components as those in the first embodiment are given the same reference numerals, and description of the components is omitted.

A method of manufacturing the semiconductor substrate will be described. FIGS. 7-1A through 7-2 are sectional views schematically showing an example of the method of manufacturing the semiconductor substrate according to the second embodiment. As shown in FIGS. 2-1A and 2-1B showing the first embodiment, the flat-shaped cavity 11 is formed on the p-type shingle crystal silicon substrate 10, and the silicon nitride film 41 is formed on the upper surface of the silicon substrate 10, and then, the film forming trench 12 leading to the cavity 11 is formed.

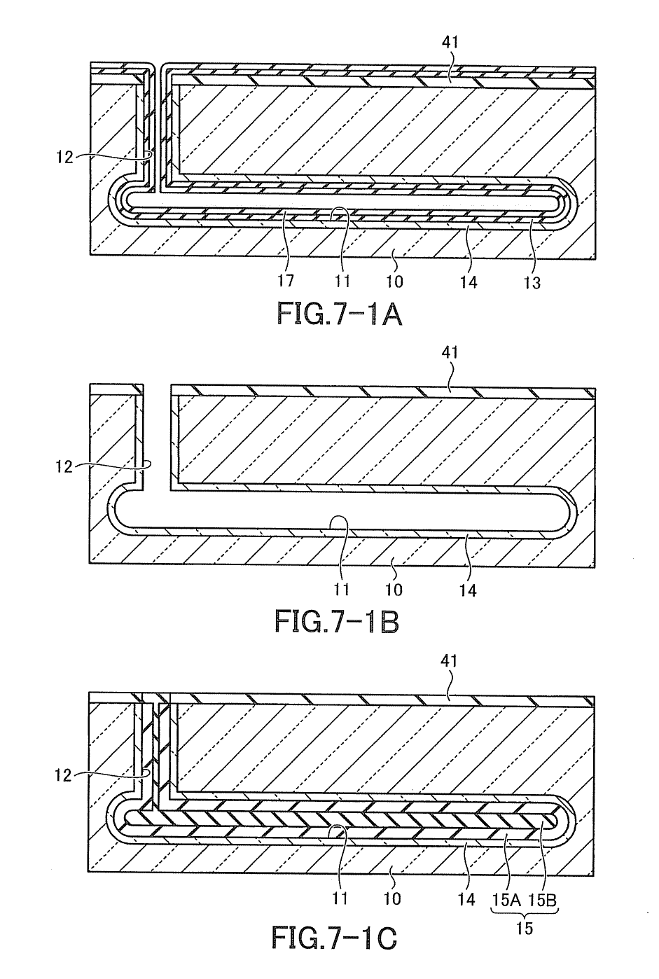

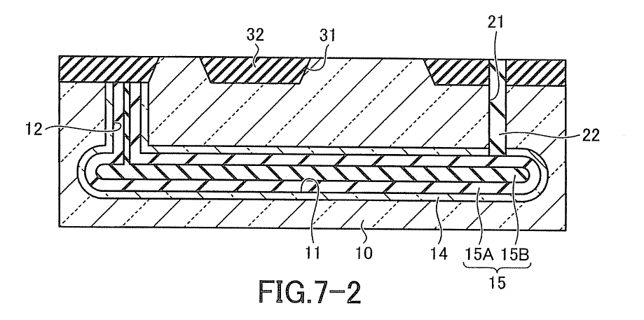

As shown in FIG. 7-1A, the n-type impurity diffusion source layer 13 formed of an AsSG film or a PSG film is formed on inner walls of the cavity 11 and the film forming trench 12 by the CVD method, and subsequently, a TEOS film 17 is deposited by the CVD method to the extent that the cavity 11 and the film forming trench 12 leading to the cavity 11 are not completely filled. After that, the n-type buried layer 14 is formed in the silicon substrate 10 around the cavity 11 through heat treatment.

As shown in FIG. 7-1B, the TEOS film 17 and the n-type impurity diffusion source layer 13 which are formed in the cavity 11 and the film forming trench 12 are removed by wet etching. As shown in FIG. 7-1C, the oxide film (the silicon oxide film 15A) is grown on the inner walls of the cavity 11 and the film forming trench 12 through thermal oxidation, and subsequently, a TEOS film 15B is formed so as to be buried into the cavity 11 and the film forming trench 12 by the CVD method. Note that, although the cavity 11 is completely filled with a TEOS film 15B without any gap in FIG. 7-1C, a gap may be left in the center portion of the flat-shaped cavity 11. However, in the film forming trench 12 formed to deposit various films in the cavity 11, at least the surface of the semiconductor substrate is covered with the TEOS film 15B. The insulating film 15 is formed of a structure in which the silicon oxide film 15A is formed along the inner wall of the cavity 11, and the TEOS film 15B is formed in the inner side of the structure.

As shown in FIG. 7-2, the DTI film 22 and the STI film 32 are formed on the element forming region where the flat-shaped insulating film 15 and the surrounding n-type buried layer 14 are formed. The DTI film 22 and the STI film 32 can be formed in the same procedure as that described in the first embodiment.

The same effects as those obtained in the first embodiment may be obtained by the second embodiment.

### Third Embodiment

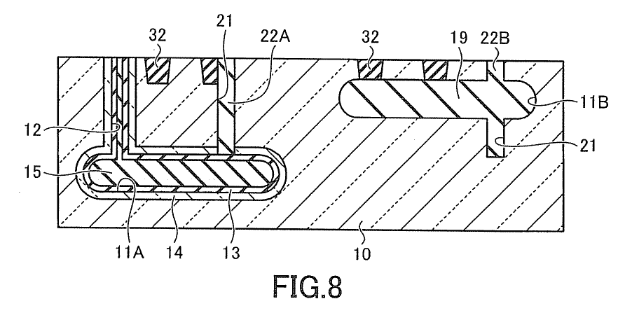

FIG. 8 is a sectional view schematically showing a part of a configuration of a semiconductor device according to a third embodiment. The semiconductor substrate has a plurality of cavities 11A, 11B having different heights from the surface of the semiconductor substrate, and has a structure in which the cavities 11A, 11B are filled with insulating films in different forms, respectively. The semiconductor substrate has two types of cavities which are the first flat-shaped cavity 11A formed to have a first depth and the second flat-shaped cavity 11B formed to have a second depth smaller than the first depth. As in the case of the first embodiment, the first cavity 11A has the film forming trench 12 connected to the first cavity 11A. The n-type impurity diffusion source layer 13 is formed along inner walls of the first cavity 11A and the film forming trench 12, and the insulating film 15 such as a TEOS film is formed so as to fill the inside of the first cavity 11A and the film forming trench 12. The n-type buried layer 14 is formed in the surrounding regions of the first cavity 11A and the film forming trench 12. The DTI film 22A extending to the insulating film 15 in the first cavity 11A is formed in a region where the first cavity 11A is formed, and the STI film 32 is formed in a shallower region.

On the other hand, only an insulating film 19 such as a TEOS film is buried in the second cavity 11B. The DTI film 22B integrated with the insulating film 19 is formed in a region where the second cavity 11B is formed as if to penetrate the second cavity 11B in the depth direction, and the STI film 32 is formed in a shallower region. A bottom of the STI film 32 overlaps the forming position of the insulating film 19. That is, the second cavity 11B is surrounded by the STI film 32 at the side in the upper portion and is surrounded by the insulating film 19 formed in the second cavity 11B in the lower portion.

A method of manufacturing the semiconductor substrate will be described. FIGS. 9-1A through 9-2C are sectional views schematically showing an example of the method of manufacturing the semiconductor device according to the third embodiment. In the following description, it is assumed herein that the region where the first cavity 11A in FIG. 8 is formed is the first element forming region R1, and the region where the second cavity 11B in FIG. 8 is formed is the second element forming region R2.

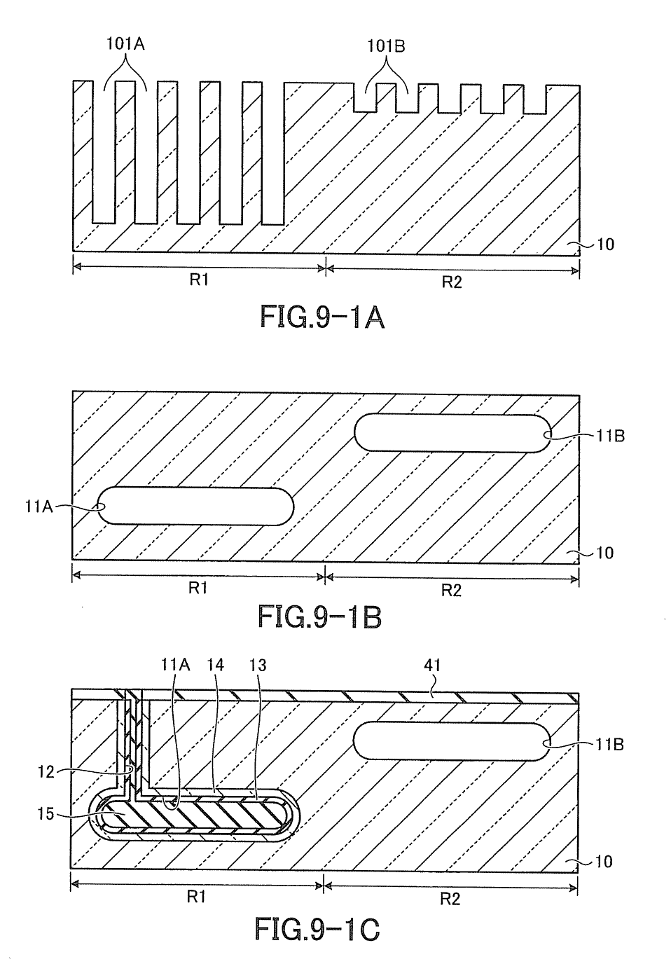

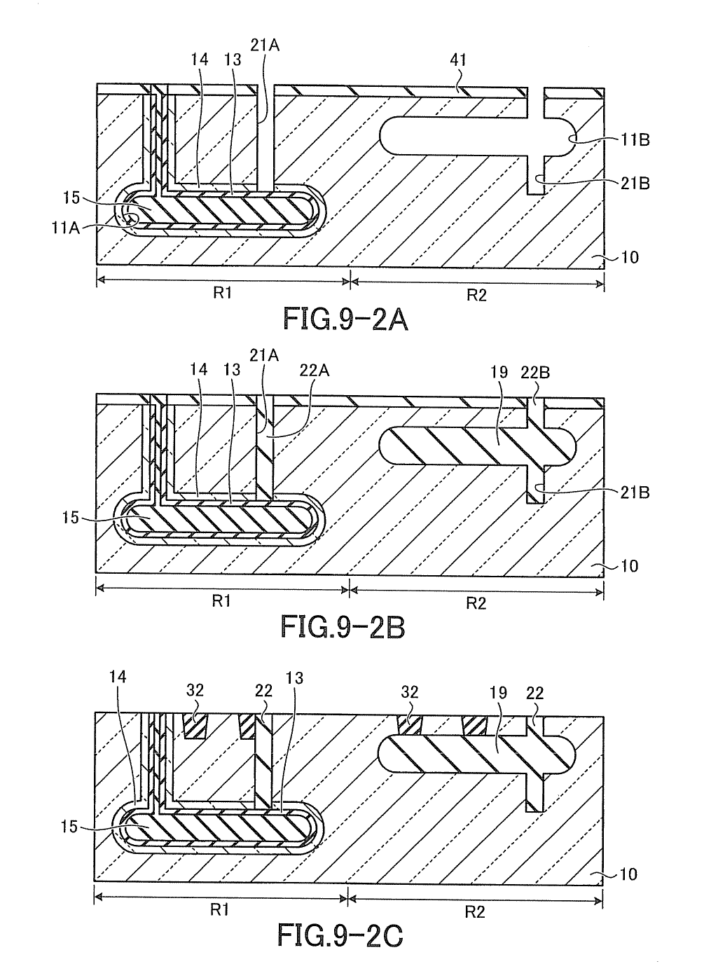

As shown in FIG. 9-1A, stripe trenches 101A, 101B are formed in the p-type shingle crystal silicon substrate 10 as the semiconductor substrate. Note that, the stripe trenches 101A, 101B have different depths depending on the location. The stripe trenches 101A each having a depth of about 5 μm, for example, from the surface of the semiconductor substrate are formed in the first element forming region R1, and the stripe trenches 101B each having a depth of about 300 nm, for example, from the surface of the semiconductor substrate are formed in the second element forming region R2. As described in the first embodiment, the trenches 101A, 101B are obtained by applying a resist on the upper surface of the silicon substrate 10, patterning the resist so that the trenches 101A, 101B to be formed can become openings and etching the silicon substrate 10 using the resist pattern by the RIE method. However, the trenches 101A in the first element forming region R1 and the trenches 101B in the second element forming region R2 are separately etched.

As shown in FIG. 9-1B, annealing at high temperature of 1100° C. in a nonoxidizing atmosphere under reduced pressure causes a migration phenomenon of silicon atoms, resulting in that opened surfaces of the trenches 101A, 101B are closed, and cavities formed at bottoms of the trenches 101A, 101B are united each other into the flat-shaped cavities 11A, 11B, respectively. The first cavity 11A is formed at a depth of about 5 μm in the first element forming region R1, and the second cavity 11B is formed at a depth of about 300 nm in the second element forming region R2.

As shown in FIG. 9-1C, according to the procedure described in the first embodiment, after the silicon nitride film 41 is formed on the upper surface of the silicon substrate 10, the film forming trench 12 leading to the first cavity 11A is formed. After the n-type impurity diffusion source layer 13 is formed in the surrounding regions of the film forming trench 12 and the first cavity 11A, the insulating film 15 such as the TEOS film is buried in the film forming trench 12 and the first cavity 11A. The n-type buried layer 14 is formed around the first cavity 11A by high-temperature annealing.

As shown in FIG. 9-2A, after a mask layer (not shown) formed of a silicon oxide film, for example, is formed on the silicon nitride film 41, a resist is applied onto the mask layer, and the resist is patterned so that the position where the DTI film is formed can be opened. The resist is patterned so that openings to form the DTI film on the first cavity 11A and the second cavity 11B are formed. The mask layer is etched using the resist pattern as a mask by the RIE method. The mask layer on which the forming position of the DTI film is opened is formed by etching. The silicon substrate 10 is etched using the mask layer as a mask by the RIE method. The etching is performed so as to extend to the insulating film 15 in the first cavity 11A. The silicon substrate 10, the n-type buried layer 14, the n-type impurity diffusion source layer 13 and the insulating film 15 are etched on the first cavity 11A, and only the silicon substrate 10 is etched on the second cavity 11B. In this manner, deep trenches 21A, 21B are formed. Here, in the second cavity 11B, the deep trench 21B is formed so as to be continuous with the second cavity 11B.

As shown in FIG. 9-2B, the insulating film 19 having initial flowability such as a TEOS film is formed in each of the deep trenches 21A, 21B and the second cavity 11B by the film-forming method such as the CVD method. The insulating film 19 is formed so that the upper surface of the insulating film 19 can be higher than the upper surface of the silicon nitride film 41. After that, the insulating film 19 on the surface of the silicon substrate 10 is removed by the CMP method or the RIE method. As in the form of the first embodiment, the DTI film 22A is formed in the first element forming region R1, the insulating film 19 having no n-type buried layer 14 is formed in the second element forming region R2, and the DTI film 22B integrated with the insulating film 19 is formed.

As shown in FIG. 9-2C, according to the same method as in the first embodiment, the STI film 32 is formed on the upper surface of the silicon substrate 10. By forming the STI film 32 having a depth extending from the surface of the semiconductor substrate to the second cavity 11B, an electrically-isolated region surrounded by an insulator can be formed in the region where the second cavity 11B is formed. The SOI configuration having the n-type buried layer 14 shown in the first embodiment and the SOI configuration having none of the n-type buried layer 14 can be formed on the same semiconductor substrate. After that, the semiconductor element is formed in the element forming region surrounded by the DTI film 22 by a well-known method.

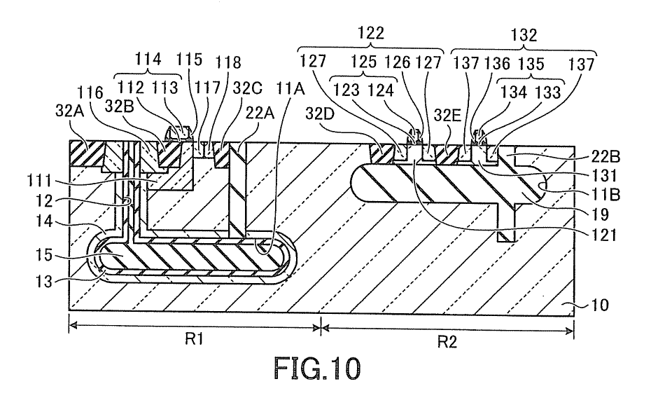

FIG. 10 is a sectional view schematically showing an example of the semiconductor device manufactured using the semiconductor substrate according to the third embodiment. In FIG. 10, it is assumed that a region corresponding to the SOI configuration having the n-type buried layer 14 is the first element forming region R1, and a region corresponding to the SOI configuration having no n-type buried layer 14 is the second element forming region R2. An LDMOS is formed in the first element forming region R1, and a complete depletion-type MOS transistor is formed in the second element forming region R2.

An LDMOS gate electrode 113 formed of a polysilicon film or the like is formed on a gate insulating film 112 in the vicinity of the center of the first element forming region R1. A side wall spacer 115 is formed on each side surface of a laminated body 114 formed of the gate insulating film 112 and the LDMOS gate electrode 113 in the line width direction. An LDMOS drain region 116 and an LDMOS source region 117 each formed of an n-type diffusion layer are formed on both sides of the laminated body 114 in the line width direction, respectively. The LDMOS drain region 116 is formed so as to be connected to the n-type buried layer 14 formed in the surrounding regions of the film forming trench 12 and the first cavity 11A. An LDMOS resurf layer 111 formed of an n-type impurity diffusion layer which has a larger depth than the LDMOS drain region 116 and a lower n-type impurity concentration than the LDMOS drain region 116 is provided from the bottom of the LDMOS gate electrode 113 to the LDMOS drain region 116. The STI film 32B exists from the bottom of the LDMOS gate electrode 113 to the LDMOS drain region 116. A base contact layer 118 formed of a p-type impurity diffusion layer having a higher concentration than the silicon substrate 10 is provided in a region between the LDMOS source region 117 and the STI film 32C.

Meanwhile, a p-type well 121 is formed in a region defined by the STI films 32D, 32E and the flat-shaped insulating film 19 in the second element forming region R2, and an n-type MOS transistor 122 is formed in the well. In the n-type MOS transistor 122, a laminated body 125 formed of a gate insulating film 123 and a gate electrode 124 is formed at a predetermined position on the silicon substrate 10, and a side wall spacer 126 is formed on each side surface of the laminated body 125 in the line width direction. Source/drain regions 127 formed of an n-type diffusion layer are formed on each side of the laminated body 125 in the line width direction and in the surface of the silicon substrate 10.

An n-type well 131 is formed in a region defined by the STI film 32E, the DTI film 22B and the flat-shaped insulating film 19 in the second element forming region R2, and a p-type MOS transistor 132 is formed in the well. In the p-type MOS transistor 132, a laminated body 135 formed of a gate insulating film 133 and a gate electrode 134 is formed at a predetermined position on the silicon substrate 10, and a side wall spacer 136 is formed on each side surface of the laminated body 135 in the line width direction. Source/drain regions 137 formed of an n-type diffusion layer are formed on each side of the laminated body 135 in the line width direction and in the surface of the silicon substrate 10.

A method of manufacturing the semiconductor device will be briefly described. A resist is applied onto the semiconductor substrate obtained through the process in FIGS. 9-2A through 9-2C and patterned by the photolithography technique so as to open a region to which ions are implanted, and then, impurity ions of each conductive type are implanted in accordance with each opening by the ion implantation method for activation. For example, in the first element forming region R1, a resist pattern in which a region corresponding to the LDMOS resurf layer 111 is opened is formed, and n-type impurity ions are implanted to form the LDMOS resurf layer 111. The ion implantation is performed on the condition that the LDMOS resurf layer 111 becomes deeper than the LDMOS drain region 116 to be formed later and has a lower n-type impurity concentration than the LDMOS drain region 116.

The gate insulating film 112 and the LDMOS gate electrode 113 are formed on the LDMOS resurf layer 111 and the STI film. 32B, and the side wall spacer 115 is formed on each side surface of the laminated body 114. A resist pattern in which a region corresponding to the LDMOS drain region 116 is opened is formed, and n-type impurity ions are implanted on the condition that the LDMOS drain region is shallower than the LDMOS resurf layer 111. In this manner, the LDMOS drain region 116 is formed. A resist pattern in which a region corresponding to the LDMOS source region 117 is opened is formed, and n-type impurity ions are implanted in the vicinity of the surface of the silicon substrate 10. In this manner, the DMOS source region 11 is formed 7. A resist pattern in which a region corresponding to the base contact layer 118 is opened is formed, and p-type impurity ions are implanted in the vicinity of the surface of the silicon substrate 10. In this manner, the base contact layer 118 is formed.

Although the n-type and p-type MOS transistors 122, 132 are formed in the second element forming region R2, description of these transistors is omitted because these transistors are the same as those described in the first embodiment.

According to the third embodiment, the cavities 11A, 11B are formed at different depths of the semiconductor substrate. The n-type buried layer 14 is formed in the surrounding region of the deeper cavity 11A, and the insulating film 15 is buried in the cavity 11A, while only the insulating film 19 is buried in the shallower cavity 11B. Therefore, elements which require different properties can be formed on the same semiconductor substrate. For example, a semiconductor element requiring a silicon layer having a thickness of a few μm such as the LDMOS and a semiconductor element requiring a thin silicon layer such as the complete depletion-type MOSFET can be formed on the same semiconductor substrate.

As a matter of course, the invention is not limited to the above-mentioned first to third embodiments and can be variously modified and applied so as not to deviate from the subject matter of the invention.

In addition, although the case where the n-type buried layer 14 is formed on the p-type silicon substrate 10 is described above, the invention is applicable to the case where a p-type buried layer is formed on an n-type silicon substrate.

What is claimed is:

1. A semiconductor device comprising:
an insulating film formed in a cavity formed inside a semiconductor substrate of a first conductivity type and in a trench extending from a surface of the semiconductor substrate to the cavity; and
a buried layer of a second conductivity type formed in surrounding regions of the cavity and the trench in the semiconductor substrate.

2. The semiconductor device according to claim 1, further comprising a diffusion source layer including an impurity of a second conductivity type between the insulating film and the buried layer.

3. The semiconductor device according to claim 1, wherein the insulating film includes: an oxide film obtained by oxidizing the semiconductor substrate, the oxide film formed along the inner walls of the cavity and the trench in the semiconductor substrate; and an insulating film formed in the cavity and the trench covered with the oxide film, the insulating film having flowability at the time of film-formation.

4. The semiconductor device according to claim 1, further comprising:
a first isolation film extending to a depth of the cavity so as to surround a predetermined region in a cavity forming region in a plane of the semiconductor substrate;
a second isolation film provided near the surface of the semiconductor substrate, the second isolation film being shallower than the first isolation film and separating adjacent regions from each other;
a resurf layer of the second conductivity type formed from the surface of the semiconductor substrate to a depth in a direction toward the buried layer in an element forming region defined by the first isolation film;
a drain region of the second conductivity type formed in the surface of the semiconductor substrate inside the resurf layer;
a source region of the second conductivity type formed in the surface of the semiconductor substrate outside the resurf layer;
a base contact layer of the first conductivity type formed in the surface of the semiconductor substrate outside the resurf layer, the base contact layer being adjacent to the source region; and
a gate electrode provided on the resurf layer between the drain region and the source region with a gate insulating film interposed between the gate electrode and the resurf layer.

5. The semiconductor device according to claim 2, wherein the insulating film includes: an oxide film obtained by oxidizing the semiconductor substrate, the oxide film formed along the inner walls of the cavity and the trench in the semiconductor substrate; and an insulating film formed in the cavity and the trench covered with the oxide film, the insulating film having flowability at the time of film-formation.

6. The semiconductor device according to claim 2, further comprising:
a first isolation film extending to a depth of the cavity so as to surround a predetermined region in a cavity forming region in a plane of the semiconductor substrate;
a second isolation film provided near the surface of the semiconductor substrate, the second isolation film being shallower than the first isolation film and separating adjacent regions from each other;
a resurf layer of the second conductivity type formed from the surface of the semiconductor substrate to a depth in a direction toward the buried layer in an element forming region defined by the first isolation film;
a drain region of the second conductivity type formed in the surface of the semiconductor substrate inside the resurf layer;
a source region of the second conductivity type formed in the surface of the semiconductor substrate outside the resurf layer;
a base contact layer of the first conductivity type formed in the surface of the semiconductor substrate outside the resurf layer, the base contact layer being adjacent to the source region; and
a gate electrode provided on the resurf layer between the drain region and the source region with a gate insulating film interposed between the gate electrode and the resurf layer.

7. The semiconductor device according to claim 3, further comprising:
a first isolation film extending to a depth of the cavity so as to surround a predetermined region in a cavity forming region in a plane of the semiconductor substrate;
a second isolation film provided near the surface of the semiconductor substrate, the second isolation film being shallower than the first isolation film and separating adjacent regions from each other;
a resurf layer of the second conductivity type formed from the surface of the semiconductor substrate to a depth in a direction toward the buried layer in an element forming region defined by the first isolation film;
a drain region of the second conductivity type formed in the surface of the semiconductor substrate inside the resurf layer;
a source region of the second conductivity type formed in the surface of the semiconductor substrate outside the resurf layer;
a base contact layer of the first conductivity type formed in the surface of the semiconductor substrate outside the resurf layer, the base contact layer being adjacent to the source region; and
a gate electrode provided on the resurf layer between the drain region and the source region with a gate insulating film interposed between the gate electrode and the resurf layer.

8. The semiconductor device according to claim 5, further comprising:
a first isolation film extending to a depth of the cavity so as to surround a predetermined region in a cavity forming region in a plane of the semiconductor substrate;
a second isolation film provided near the surface of the semiconductor substrate, the second isolation film being shallower than the first isolation film and separating adjacent regions from each other;
a resurf layer of the second conductivity type formed from the surface of the semiconductor substrate to a depth in a direction toward the buried layer in an element forming region defined by the first isolation film;
a drain region of the second conductivity type formed in the surface of the semiconductor substrate inside the resurf layer;
a source region of the second conductivity type formed in the surface of the semiconductor substrate outside the resurf layer;
a base contact layer of the first conductivity type formed in the surface of the semiconductor substrate outside the resurf layer, the base contact layer being adjacent to the source region; and
a gate electrode provided on the resurf layer between the drain region and the source region with a gate insulating film interposed between the gate electrode and the resurf layer.

9. The semiconductor device according to claim 2, wherein the diffusion source layer is an AsSG film or a PSG film.

10. The semiconductor device according to claim 5, wherein the diffusion source layer is an AsSG film or a PSG film.

11. The semiconductor device according to claim 6, wherein the diffusion source layer is an AsSG film or a PSG film.

12. The semiconductor device according to claim 1, wherein the cavity is flat-shaped.

13. The semiconductor device according to claim 3, wherein the insulating film having flowability at the time of film-formation is a TEOS film.

14. The semiconductor device according to claim 5, wherein the insulating film having flowability at the time of film-formation is a TEOS film.

15. The semiconductor device according to claim 7, wherein the insulating film having flowability at the time of film-formation is a TEOS film.

16. The semiconductor device according to claim 8, wherein the insulating film having flowability at the time of film-formation is a TEOS film.

17. The semiconductor device according to claim 10, wherein the insulating film having flowability at the time of film-formation is a TEOS film.

18. A method of manufacturing a semiconductor device comprising:
forming a cavity in a predetermined depth inside a semiconductor substrate of a first conductivity type;
forming a trench extending from a surface of the semiconductor substrate to the cavity;
forming an impurity diffusion source layer including an impurity of a second conductivity type on inner walls of the cavity and the trench through the trench;
forming an insulating film on the impurity diffusion source layer formed inside the cavity and the trench through the trench; and
forming a buried layer by diffusing the impurity of the second conductivity type included in the impurity diffusion source layer into the semiconductor substrate around the cavity through heat treatment.

19. The method according to claim 18, wherein forming the cavity includes forming a plurality of stripe trenches from the surface of the semiconductor substrate to the depth inside the semiconductor substrate and then annealing at high temperature.

20. The method according to claim 18, wherein the cavity is flat-shaped.
